(19) United States
(12) Patent Application Publication
(10) Pub. No.: US 2025/0338689 A1
(43) Pub. Date: Oct. 30, 2025

(54) DISPLAY DEVICE

(71) Applicant: LG Display Co., Ltd., Seoul (KR)

(72) Inventors: DanLyoul Ma, Seoul (KR); Hyoungsun Park, Seoul (KR); Hyunseok Na, Hwaseong-si (KR)

(73) Assignee: LG Display Co., Ltd., Seoul (KR)

(21) Appl. No.: 19/091,672

(22) Filed: Mar. 26, 2025

(30) Foreign Application Priority Data
Apr. 26, 2024 (KR) 10-2024-0056040

(51) Int. Cl. H10H 29/37; H10H 29/01; H10H 29/49; H10H 29/80

(52) U.S. Cl. CPC H10H 29/37; H10H 29/49; H10H 29/8321; H10H 29/882; H10H 29/012

(57) ABSTRACT

A display device includes a plurality of light-emitting elements and barrier ribs disposed on the plurality of first electrodes; a light-emitting element disposed between the plurality of barrier ribs; a first optical layer disposed between the plurality of light-emitting elements; and a second electrode disposed on the plurality of light-emitting elements, in which the second electrode includes a first area disposed on the plurality of light-emitting elements and a second area extending outwardly from the first optical layer and electrically connected to the contact electrode.

### CROSS-REFERENCE TO RELATED APPLICATIONS

This application claims the priority of Korean Patent Application No. 10-2024-0056040 filed on Apr. 26, 2024, in the Korean Intellectual Property Office, the disclosure of which is incorporated herein by reference.

### BACKGROUND

### Technical Field

The present disclosure relates to a display device, and more particularly, to a display device using a light emitting diode (LED).

### Discussion of the Related Art

As display devices which are used for a monitor of a computer, a television, a cellular phone, or the like, there are an organic light emitting display (OLED) device which is a self-emitting device and a liquid crystal display (LCD) device which requires a separate light source.

An applicable range of the display device is diversified to personal mobile devices as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance can be displayed.

### SUMMARY

Accordingly, embodiments of the present disclosure are directed to a display device that substantially obviates one or more of the problems due to limitations and disadvantages of the related art.

An aspect of the present disclosure is to provide a display device capable of suppressing occurrence of a short circuit defect between an upper electrode and a lower electrode even when a light-emitting element is not transferred by disposing a barrier rib above a bank.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a plurality of first electrodes and a contact electrode disposed on a substrate; a plurality of light-emitting elements and barrier ribs disposed on the plurality of first electrodes; a light-emitting element disposed between the plurality of barrier ribs; a first optical layer disposed between the plurality of light-emitting elements; and a second electrode disposed on the plurality of light-emitting elements, in which the second electrode includes a first area disposed on the plurality of light-emitting elements and a second area extending outwardly from the first optical layer and electrically connected to the contact electrode.

Other detailed matters of the exemplary embodiments are included in the detailed description and the drawings.

According to the present disclosure, it is possible to suppress a short circuit defect between an upper electrode and a lower electrode even when the light-emitting element is not transferred by disposing the barrier rib above the bank.

According to the present disclosure, it is possible to suppress misalignment of the light-emitting element when the light-emitting element is transferred by disposing the barrier rib above the bank.

It is to be understood that both the foregoing general description and the following detailed description are exemplary and explanatory and are intended to provide further explanation of the inventive concepts as claimed.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view illustrating a display device according to one exemplary embodiment of the present disclosure;

FIG. 2 is an enlarged view illustrating an area A in FIG. 1;

FIG. 3 is a view illustrating a portion of a pixel;

FIG. 4 is a cross-sectional view taken along line I-I′ in FIG. 3;

FIG. 5 is a view illustrating another exemplary embodiment of FIG. 4;

FIG. 6 is a cross-sectional view taken along line II-II′ in FIG. 3;

FIG. 7 is a cross-sectional view taken along line III-III′ in FIG. 3;

FIGS. 8A to 8D are views illustrating a method for manufacturing a first barrier rib of a display device according to one exemplary embodiment of the present disclosure; and

FIGS. 9A to 9D are views illustrating a method for manufacturing a second barrier rib of a display device according to one exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

A display device according to one exemplary embodiment of the present disclosure includes a display area in which an image is displayed, a display panel in which a screen is disposed, and a pixel driving circuit for driving pixels of the display panel. The display area includes a pixel area in which pixels are disposed. The pixel area includes a plurality of light-emitting areas. A light-emitting element is disposed in each of the light-emitting areas. The pixel driving circuit may be built into the display panel.

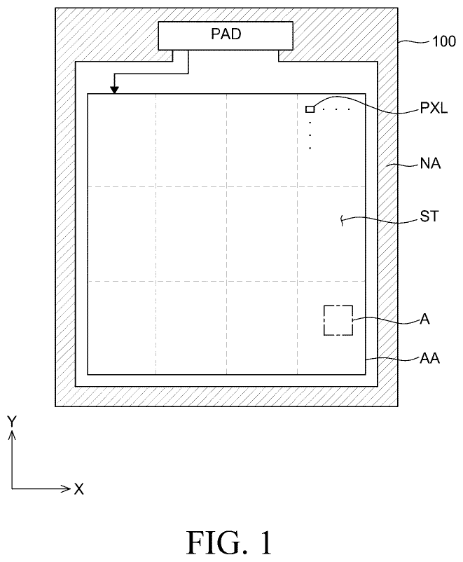

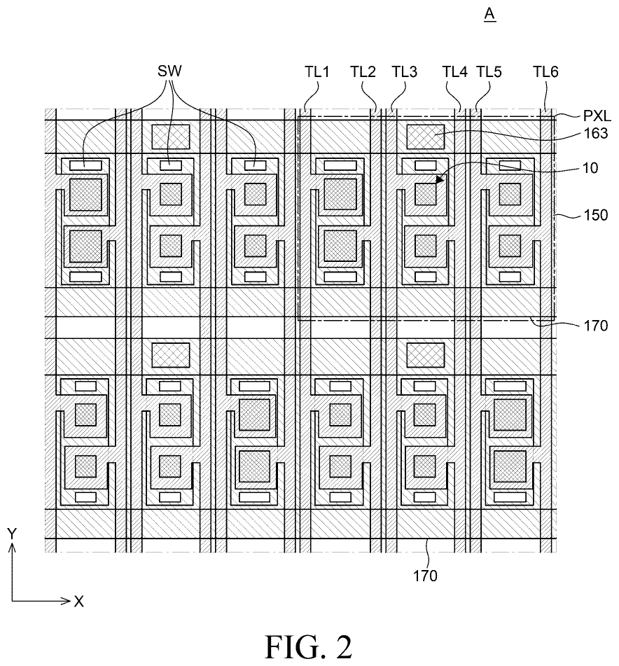

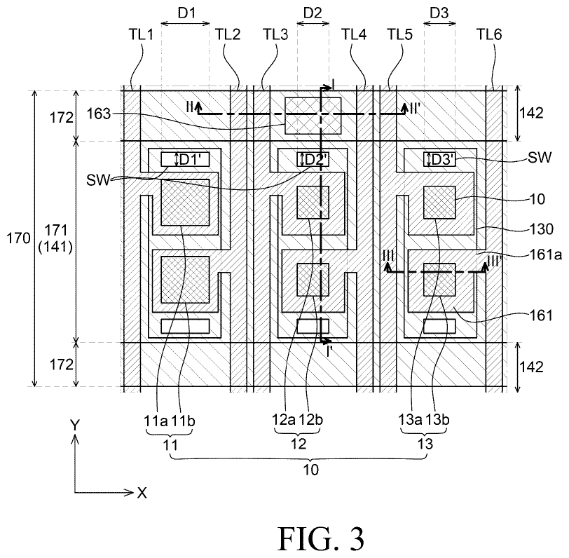

FIG. 1 is a view illustrating a display device according to one exemplary embodiment of the present disclosure. FIG. 2 is an enlarged view illustrating an area A of FIG. 1. FIG. 3 is a view illustrating a portion of a pixel. In FIG. 3, for convenience of illustration, the illustration of configurations of a black matrix 190 and a cover layer 180 is omitted.

Referring to FIGS. 1 and 2, a display device 100 according to an exemplary embodiment of the present disclosure includes a display panel on which an input image is visually reproduced. The display panel may include a display area AA on which an image is displayed and a non-display area NA on which an image is not displayed. Various wires and driving circuits may be mounted in the non-display area NA, and a pad portion PAD on which an integrated circuit and a printed circuit are connected may be disposed in the non-display area NA.

A plurality of light-emitting elements 10 disposed in the display area AA to form a pixel PXL may be micro-sized inorganic light-emitting elements. The inorganic light-emitting elements may be grown on a silicon wafer and then attached to the display panel through a transfer process.

The transfer process of the light-emitting element 10 may be performed for each pre-divided area. In FIG. 1, the display area AA is divided into 12 transfer areas ST as an example, but the size of the transfer areas or the number of divisions is not limited thereto. The transfer process may be performed sequentially or simultaneously in the first transfer area ST to the twelfth transfer area ST. In each transfer area ST, a blue light-emitting element, a green light-emitting element, and a red light-emitting element may be sequentially transferred.

A data driving circuit or a gate driving circuit may be disposed in the non-display area NA, and wires to which control signals for controlling these driving circuits are supplied may be disposed in the non-display area NA. Here, the control signal includes various timing signals including a clock signal, an input data enable signal, and synchronization signals, and may be received through a pad portion PAD.

The pixels PXL may be driven by the pixel driving circuit. The pixel driving circuit may receive a driving voltage, an image signal (digital signal), a synchronization signal synchronized with the image signal, or the like, and may drive the plurality of pixels by outputting an anode voltage and a cathode voltage of the light-emitting element 10. The driving voltage may be a high-potential voltage EVDD. The cathode voltage may be a low-potential voltage EVSS commonly applied to the pixels. The anode voltage may be a voltage corresponding to a pixel data value of the image signal. The pixel driving circuit may be disposed in the non-display area NA or may be disposed below the display area AA.

Each of the pixels PXL may include a plurality of sub-pixels having different colors. For example, the plurality of pixels may include a red sub-pixel in which the light-emitting element 10 emitting light of a red wavelength is disposed, a green sub-pixel in which the light-emitting element 10 emitting light of a green wavelength is disposed, and a blue sub-pixel in which the light-emitting element 10 emitting light of a blue wavelength is disposed. The plurality of pixels may further include a white pixel.

Referring to FIGS. 2 and 3, the plurality of pixels PXL may be disposed sequentially in a first direction (X-axis direction) and a second direction (Y-axis direction). A plurality of sub-pixels of the same color may be disposed within the pixel PXL of the display area AA. For example, each of the plurality of pixels PXL may include a first red sub-pixel in which a 1-1st light-emitting element 11a emitting light of a red wavelength is disposed, a second red sub-pixel in which a 1-2nd light-emitting element 11b emitting light of a red wavelength is disposed, a first green sub-pixel in which a 2-1st light-emitting element 12a emitting light of a green wavelength is disposed, a second green sub-pixel in which a 2-2nd light-emitting element 12b emitting light of a green wavelength is disposed, a first blue sub-pixel in which a 3-1st light-emitting element 13a emitting light of a blue wavelength is disposed, and a second blue sub-pixel in which a 3-2nd light-emitting element 13b emitting light of a blue wavelength is disposed. The 1-1st light-emitting element 11a, the 2-1st light-emitting element 12a, and the 3-1st light-emitting element 13a may be interpreted as main light-emitting elements. The 1-2nd light-emitting element 11b, the 2-2nd light-emitting element 12b, and the 3-2nd light-emitting element 13b may be interpreted as sub light-emitting elements.

One sub-pixel may include at least one light-emitting element, and when one light-emitting element becomes defective, the brightness of the sub-pixel may be adjusted by increasing the brightness of other light-emitting elements. However, this is not necessarily limited thereto, and one sub-pixel may include only one light-emitting element.

The plurality of light-emitting elements 10 may be disposed between a plurality of barrier ribs SW. For example, the plurality of barrier ribs SW may be disposed in the second direction (Y-axis direction), and light-emitting elements 10 may be disposed between the barrier ribs SW.

The sizes of some of the light-emitting elements 10 among the plurality of light-emitting elements 10 may be different from each other. For example, as illustrated in FIG. 3, lengths D1 in the first direction (X-axis direction) and the second direction (Y-axis direction) of the first light-emitting element 11 emitting light of a red wavelength and lengths D2 in the first direction (X-axis direction) and second direction (Y-axis direction) of the second light-emitting element 12 emitting light of a green wavelength may be different from each other. In addition, the lengths D1 in the first direction (X-axis direction) and second direction (Y-axis direction) of the first light-emitting element 11 and lengths D3 in the first direction (X-axis direction) and second direction (Y-axis direction) of the third light-emitting element 13 emitting light of a blue wavelength may be different from each other.

Meanwhile, the sizes of some of the light-emitting elements 10 among the plurality of light-emitting elements 10 may be the same as each other. For example, as illustrated in FIG. 3, the lengths D2 in the first direction (X-axis direction) and second direction (Y-axis direction) of the second light-emitting element 12 emitting light of a green wavelength and the lengths D3 in the first direction (X-axis direction) and second direction (Y-axis direction) of the third light-emitting element 13 emitting light of a blue wavelength may be the same as each other.

The lengths D1 in the first direction (X-axis direction) and second direction (Y-axis direction) of the first light-emitting element 11 may be longer than the lengths D2 in the first direction (X-axis direction) and second direction (Y-axis direction) of the second light-emitting element 12 and the lengths D3 in the first direction (X-axis direction) and second direction (Y-axis direction) of the third light-emitting element 13.

A length in the first direction (X-axis direction) of the barrier rib SW may be the same as the length in the first direction of the disposed light-emitting element 10. The lengths in the first direction (X-axis direction) and the second direction (Y-axis direction) of the barrier rib SW may be different from each other. For example, lengths D1, D2 and D3 in the first direction (X-axis direction) of the barrier rib SW may be twice lengths D1′, D2′ and D3′ in the second direction (Y-axis direction) of the barrier rib SW, but are not limited thereto.

A plurality of first electrodes 161 are disposed below the light-emitting element 10 and may be selectively connected to a plurality of signal wires TL1 to TL6 by an extension portion 161a. A high potential voltage maybe applied to the pixel driving circuit through the signal wires TL1 to TL6. The signal wires TL1 to TL6, the extension portion 161a, and the first electrode 161 may be formed as an integrated pattern during a patterning process.

For example, a first signal wire TL1 may be connected to an anode electrode of the first red sub-pixel, and a second signal wire TL2 may be connected to an anode electrode of the second red sub-pixel. A third signal wire TL3 may be connected to an anode electrode of the first green sub-pixel, and a fourth signal wire TL4 may be connected to an anode electrode of a second green sub-pixel. A fifth signal wire TL5 may be connected to an anode electrode of the first blue sub-pixel, and a sixth signal wire TL6 may be connected to an anode electrode of a second blue sub-pixel. When one sub-pixel includes only one light-emitting element 10, the number of signal wires TL may be reduced by half.

A second electrode 170 may be disposed in each row and may be continuously disposed in the first direction (X-axis direction) and may be a cathode electrode that applies a cathode voltage to the light-emitting element 10. A plurality of second electrodes 170 may be disposed spaced apart from each other in the second direction (Y-axis direction). The plurality of second electrodes 170 may receive the cathode voltage through a contact electrode 163. Each of the plurality of second electrodes 170 may be electrically connected to the contact electrode 163. However, it is not necessarily limited thereto, and the second electrode 170 may not be divided into a plurality of pieces but may be formed as a single electrode layer to function as a common electrode.

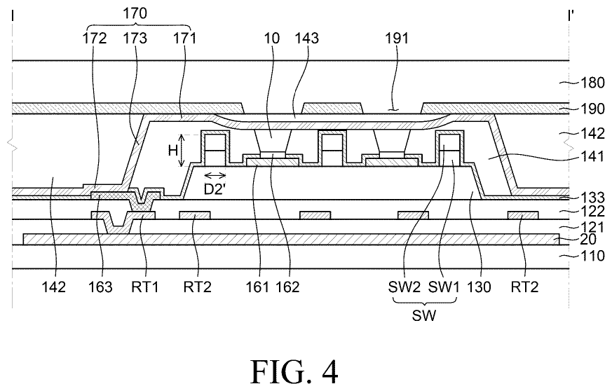

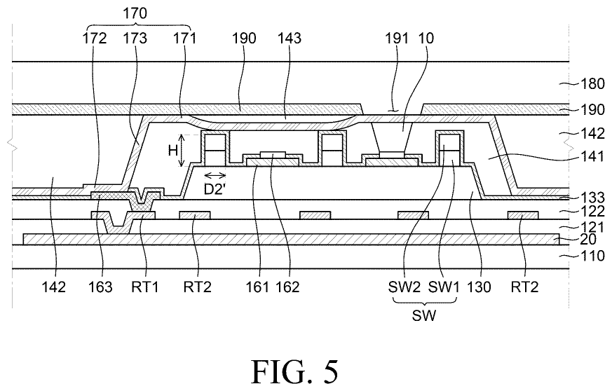

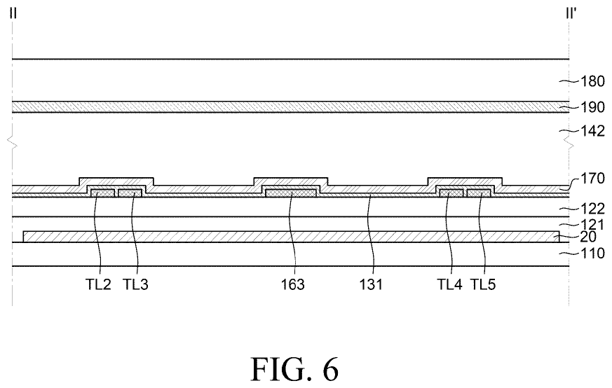

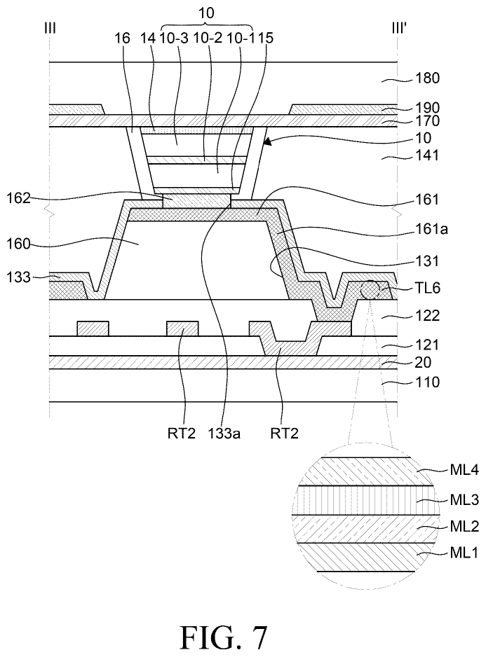

FIG. 4 is a cross-sectional view taken along line I-I′ of FIG. 3. FIG. 5 is a view illustrating another exemplary embodiment of FIG. 4. Specifically, FIG. 5 is an example in which one light-emitting element 10 is not transferred in FIG. 4. FIG. 6 is a cross-sectional view taken along line II-II′ of FIG. 3. FIG. 7 is a cross-sectional view taken along line III-III′ of FIG. 3.

Referring to FIGS. 3 to 6, the display device 100 according to an exemplary embodiment includes a bank pattern 130, a plurality of first electrodes 161, and a contact electrode 163 disposed on a substrate 110. The display device 100 includes the plurality of barrier ribs SW disposed on the bank pattern 130, the plurality of light-emitting elements 10 disposed on the plurality of first electrodes 161, a first optical layer 141 disposed between the plurality of light-emitting elements 10, and a second electrode 170 disposed on the plurality of light-emitting elements 10.

The substrate 110 may be made of a flexible plastic. For example, the substrate 110 may be made of a single-layer or multi-layer substrate made of a material selected from among polyimide, polyethylene terephthalate, polyethylene naphthalate, polycarbonate, polyethersulfone, polyarylate, polysulfone, and cyclic-olefin copolymer, but is not limited thereto. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes a plurality of thin film transistors, the pixel driving circuit 20 may be formed on the substrate 110 by a thin film transistor (TFT) manufacturing process. In an exemplary embodiment, the pixel driving circuit 20 may be a concept that collectively refers to a plurality of thin film transistors that is electrically connected to the light-emitting element 10.

The pixel driving circuit 20 may be a driving driver manufactured using a metal-oxide-silicon field effect transistor (MOFET) manufacturing process on a single crystal semiconductor substrate 110. The driving driver may include a plurality of pixel driving circuits to drive a plurality of sub-pixels. When the pixel driving circuit 20 is implemented as a driving driver, after an adhesive layer is disposed on the substrate 110, the driving driver may be mounted on the adhesive layer by a transfer process.

A buffer layer 121 covering the pixel driving circuit 20 may be disposed on the substrate 110. The buffer layer 121 may be made of an organic insulating material, for example, photosensitive photo acryl or photosensitive polyimide, but is not limited thereto. Alternatively, the buffer layer 121 may be configured by laminating a plurality of layers of inorganic insulating materials, for example, silicon nitride (SiNx) or silicon oxide (SiO2). Alternatively, the buffer layer 121 may be used by laminating a plurality of layers of organic insulating materials and inorganic insulating materials.

Connecting wires RT1 and RT2 may be disposed on the buffer layer 121. The connecting wires RT1 and RT2 may be connected to corresponding signal wires TL1 to TL6. In FIGS. 4 and 5, the connecting wires RT1 and RT2 are illustrated as a single wiring pattern disposed on the same layer, but are not limited thereto, and the connecting wires RT1 and RT2 may include a plurality of wiring patterns disposed on different layers with one or more insulating layers interposed therebetween. The wiring patterns disposed on different layers may be electrically connected through contact holes penetrating the insulating layers.

An insulating layer 122 may be placed on the buffer layer 121 and the connecting wires RT1 and RT2. The insulating layer 122 may be made of an organic insulating material, for example, photosensitive photo acryl or photosensitive polyimide, but is not limited thereto.

A plurality of bank patterns 130 may be disposed on the insulating layer 122. At least one light-emitting element 10 may be disposed on each bank pattern 130. For example, the first light-emitting element 11 may be disposed on a first bank pattern, the second light-emitting element 12 may be disposed on a second bank pattern, and the third light-emitting element 13 may be disposed on a third bank pattern.

The bank pattern 130 may be made of an organic insulating material, for example, photosensitive photo acryl or photosensitive polyimide, but is not limited thereto. The bank pattern 130 may guide a position where the light-emitting element 10 is to be attached during the transfer process of the light-emitting element 10. The bank pattern 130 may be omitted.

The plurality of barrier ribs SW may be disposed on the bank pattern 130. The plurality of barrier ribs SW may include a first barrier rib SW1 and a second barrier rib SW2 disposed on the first barrier rib SW1. Without being limited thereto, the barrier ribs SW may be formed of a single layer. The light-emitting element 10 may be disposed between the plurality of barrier ribs SW. For example, one light-emitting element 10 may be disposed between the plurality of barrier ribs SW.

Referring to FIG. 4, when the light-emitting element 10 is transferred between a plurality of barrier ribs SW, the problem of the light-emitting element 10 being misaligned can be suppressed by the plurality of barrier ribs SW. For example, when the light-emitting element 10 is transferred onto the bank pattern 130, the plurality of barrier ribs SW may guide the transfer position of the light-emitting element 10. Accordingly, even when the light-emitting element 10 is misaligned and transferred onto the bank pattern 130, the plurality of barrier ribs SW may guide the position and transfer direction of the light-emitting element 10, so that the problem of the light-emitting element 10 being misaligned may be minimized.

Referring to FIG. 5, when the light-emitting element 10 is not transferred, a defect in which the second electrode 170 is short-circuited with the first electrode 161 and/or a solder pattern 162 may be suppressed by the plurality of barrier ribs SW. Specifically, as illustrated in FIG. 5, in a case where the light-emitting element that should be transferred on the first electrode 161 disposed on the left is not transferred, when there is no plurality of barrier ribs SW, the second electrode 170 may be electrically connected to the first electrode 161 and/or the solder pattern 162, resulting in a short-circuit. However, since the plurality of barrier ribs SW is disposed, the second electrode 170 is supported by the plurality of barrier ribs SW, and thus the second electrode 170 may be disposed to be spaced apart from the first electrode 161 and/or the solder pattern 162. Accordingly, in the display device 100 according to one exemplary embodiment of the present disclosure, even when the light-emitting element is not transferred, the problem of the second electrode 170 being short-circuited with the first electrode 161 and/or the solder pattern 162 by the plurality of barrier ribs SW may be suppressed.

The plurality of first electrodes 161 may be disposed on the bank pattern 130. A passivation layer 133 may be disposed to cover a portion above the first electrode 161, the entire barrier rib SW, and the entire bank pattern 130. The passivation layer 133 may expose the contact electrode 163 so that the contact electrode 163 and the second electrode 170 are electrically connected. In addition, the passivation layer 133 may insulate the signal wires TL2 to TL5 and the second electrode 170. The passivation layer 133 may be formed of an inorganic material, for example, silicon nitride (SiNx) or silicon oxide (SiO2).

A plurality of solder patterns 162 may be disposed on the plurality of first electrodes 161. The plurality of solder patterns 162 maybe made of indium (In), tin (Sn), or an alloy thereof, but is not limited thereto.

The plurality of light-emitting elements 10 may be mounted on the plurality of solder patterns 162, respectively. One pixel may include light-emitting elements 10 of three colors. The first light-emitting element 11 may be a red light-emitting element, the second light-emitting element 12 may be a green light-emitting element, and the third light-emitting element 13 may be a blue light-emitting element. Two light-emitting elements may be mounted on each sub-pixel.

The first optical layer 141 may cover the plurality of light-emitting elements 10 and the bank pattern 130. Therefore, the first optical layer 141 may cover between the plurality of light-emitting elements 10 and between the plurality of bank patterns 130. The first optical layer 141 may extend in the first direction (X-axis direction) and be separated between pixel rows in the second direction (Y-axis direction).

The first optical layer 141 may include an organic insulating material in which fine metal particles, such as titanium dioxide particles, are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be commonly connected to the plurality of pixels PXL. The second electrode 170 may be a thin electrode through which light is transmitted. The second electrode 170 may be a transparent electrode material, for example, indium tin oxide (ITO), but is not necessarily limited thereto.

The second electrode 170 may extend in the first direction (X-axis direction) and be spaced apart in the second direction (Y-axis direction). The second electrode 170 may include a first portion 171 disposed on the upper surface of the light-emitting element 10 and the upper surface of the first optical layer 141, a second portion 172 in contact with the contact electrode 163 and electrically connected to the contact electrode 163, and a third portion 173 disposed on the side surface of the first optical layer 141 and connecting the first portion 171 and the second portion 172.

On the plane, the first portion 171 and the third portion 173 of the plurality of second electrodes 170 may overlap the first optical layer 141, and the second portion 172 may cover the plane on the outer side of the first optical layer 141.

A second optical layer 142 may be an organic insulating material surrounding the first optical layer 141. The second optical layer 142 may be disposed on the insulating layer 122 together with the first optical layer 141. The first optical layer 141 and the second optical layer 142 may include the same material (for example, siloxane). For example, the first optical layer 141 may be a siloxane including titanium oxide (TiOx), and the second optical layer 142 may be a siloxane not including titanium oxide (TiOx). However, it is not necessarily limited thereto, and the first optical layer 141 and the second optical layer 142 may be formed of the same material or may be formed of different materials.

According to an exemplary embodiment, the second portion 172 of the second electrode 170 is connected to the contact electrode 163 in a state in which the second portion 172 is formed flat overall, so that excessive stress is not concentrated at the point where the second portion 172 is connected to the contact electrode 163. Accordingly, the occurrence of cracks in the second electrode 170 may be effectively suppressed.

The second optical layer 142 may cover the second portion 172 and the third portion 173 of the second electrode 170. The upper surface of the second optical layer 142 and the upper surface of the first portion 171 of the second electrode 170 may form the same plane.

A third optical layer 143 may be an organic insulating material disposed above the second electrode 170. The third optical layer 143 may be disposed to overlap the first optical layer 141. The third optical layer 143 may be formed of the same material as the first optical layer 141 or may be formed of a different material.

The upper surface of the second optical layer 142, the upper surface of the third optical layer 143, and the upper surface of the first portion 171 of the second electrode 170 may form the same plane. That is, the first optical layer 141, the second optical layer 142, and the third optical layer 143 may function as planarization layers. Accordingly, since there is no step on the surface where the black matrix 190 is formed, the pattern of the black matrix 190 may be easily formed on the first optical layer 141, the second optical layer 142, and the third optical layer 143. However, it is not necessarily limited thereto, and the upper surfaces of the second optical layer 142 and the second electrode 170 may have different heights.

The black matrix 190 may be an organic insulating material to which black pigment is added. The second electrode 170 may be in contact with the contact electrode 163 below the black matrix 190. A transmission hole 191 through which light emitted from the light-emitting element 10 is emitted to the outside may be formed between the patterns of the black matrix 190. The problem of light emitted from an adjacent light-emitting element 10 being mixed by the first optical layer 141 may be improved due to the black matrix 190.

The cover layer 180 may be disposed to cover the black matrix 190 and the second electrode 170. The cover layer 180 may be made of an organic insulating material, but is not limited thereto.

The contact electrode 163 is electrically connected to the first connecting wire RT1 disposed below the contact electrode 163, and the first connecting wire RT1 may be connected to the pixel driving circuit 20. Accordingly, the second electrode 170 may be applied with a cathode voltage through the contact electrode 163. The first electrode 161 may be electrically connected to the second connecting wire RT2. This will be described later.

Referring to FIG. 6, the contact electrode 163 and the signal wires TL1 to TL6 may be disposed on the same plane. The pixel driving circuit 20 may be disposed below the contact electrode 163 and the signal wires TL1 to TL6. When the pixel driving circuit 20 is a driving driver, a plurality of driving drivers may be disposed within the display panel.

The passivation layer 133 may expose the contact electrode 163 so that the contact electrode 163 and the second electrode 170 are electrically connected. In addition, the passivation layer 133 may insulate the signal wires TL2 to TL5 and the second electrode 170.

Referring to FIG. 7, the extension portion 161a of the first electrode 161 may be electrically connected to the connecting wire RT2 that extends to one side surface 131 of the bank pattern 130 and is disposed on the insulating layer 122.

The first electrode 161, the extension portion 161a, the signal wire TL, and/or the connecting wires RT1 and RT2 may include a single-layer or multi-layer metal layer selected from titanium (Ti), molybdenum (Mo), aluminum (Al), indium tin oxide (ITO), and indium zinc oxide (IZO). The first electrode 161, the extension portion 161a, the signal wire TL, and/or the connecting wires RT1 and RT2 may be formed as a multi-layer structure including a first layer ML1, a second layer ML2, a third layer ML3, and a fourth layer ML4.

The first layer ML1 and the third layer ML3 may include titanium (Ti) or molybdenum (Mo). The second layer ML2 may include aluminum (Al). The fourth layer ML4 may include a transparent conductive oxide layer, such as indium tin oxide (ITO) or indium zinc oxide (IZO), which has good adhesion to the solder pattern 162 and corrosion resistance and acid resistance.

The first layer ML1, second layer ML2, third layer ML3, and fourth layer ML4 may be sequentially deposited and then patterned by performing a photolithography process and an etching process.

The passivation layer 133 may be disposed on the first electrode 161 and the signal wire TL and may include an opening 133a that exposes the solder pattern 162. For example, the passivation layer 133 may be disposed on a portion of the upper surface of the fourth layer ML4. The passivation layer 133 may be disposed on the upper surface of the fourth layer ML4 to protect the fourth layer ML4.

The light-emitting element 10 may include a first conductive semiconductor layer 10-1, an active layer 10-2 disposed on the first conductive semiconductor layer 10-1, and a second conductive semiconductor layer 10-3 disposed on the active layer 10-2. A first driving electrode 15 may be disposed below the first conductive semiconductor layer 10-1, and a second driving electrode 14 may be disposed above the second conductive semiconductor layer 10-3. The light-emitting element 10 may be bonded to the solder pattern 162 through eutectic bonding in the opening 133a. For example, gold (Au) attached to the lower portion of the light-emitting element 10 and indium (In) of the solder pattern 162 may be bonded.

The light-emitting element 10 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), and sputtering.

The first conductive semiconductor layer 10-1 may be implemented with a compound semiconductor of group III-V, group II-VI, or the like, and may be doped with a first dopant. The first conductive semiconductor layer 10-1 may be formed of any one or more of a semiconductor material having a composition formula of Alx1Iny1Ga(1−x1−y1)N (0≤x1≤1, 0≤y1≤1, 0≤x1+y1≤1), InAlGaN, AlGaAs, GaP, GaAs, GaAsP, AlGaInP, but is not limited thereto. When the first dopant is an n-type dopant such as Si, Ge, Sn, Se and Te, or the like, the first conductive semiconductor layer 10-1 may be an n-type nitride semiconductor layer. However, when the first dopant is a p-type dopant, the first conductive semiconductor layer 10-1 may be a p-type nitride semiconductor layer.

The active layer 10-2 is a layer where electrons (or holes) injected through the first conductive semiconductor layer 10-1 and holes (or electrons) injected through the second conductive semiconductor layer 10-3 meet. The active layer 10-2 transitions to a lower energy level as electrons and holes recombine, and may generate light having a corresponding wavelength.

The active layer 10-2 may have any one of a single well structure, a multi-well structure, a single quantum well structure, a multi quantum well (MQW) structure, a quantum dot structure, or a quantum wire structure, and the structure of the active layer 10-2 is not limited thereto. The active layer 10-2 may generate light in a visible light wavelength range. For example, the active layer 10-2 may output light of wavelength range corresponding to any one of a blue, green, and red.

The second conductive semiconductor layer 10-3 may be disposed on the active layer 10-2. The second conductive semiconductor layer 10-3 may be implemented with a compound semiconductor of group III-V, group II-VI, or the like, and a second dopant may be doped into the second conductive semiconductor layer 10-3. The second conductive semiconductor layer 10-3 may be formed of a semiconductor material having a composition formula of Inx2Aly2Ga1−x2−y2N (0≤x2≤1, 0≤y2≤1, 0≤x2+y2≤1) or a material selected from among AlInN, AlGaAs, GaP, GaAs, GaAsP, and AlGaInP. When the second dopant is a p-type dopant such as Mg, Zn, Ca, Sr, or Ba, the second conductive semiconductor layer 10-3 doped with the second dopant may be a p-type semiconductor layer. When the second dopant is an n-type dopant, the second conductive semiconductor layer 10-3 may be an n-type nitride semiconductor layer.

A reflective layer 16 may be disposed on the side surface of and below the light-emitting element 10. The reflective layer 16 may have a structure in which a reflective material is dispersed in a resin layer, but is not necessarily limited thereto. For example, the reflective layer 16 may be manufactured as a reflector of various structures. Light emitted from the active layer 10-2 by the reflective layer 16 may be reflected upward, thereby increasing light extraction efficiency.

In the exemplary embodiment, a vertical structure is described in which the driving electrodes 14 and 15 are disposed above and below the light-emitting element 10, but the light-emitting element may have a lateral structure or a flip chip structure in addition to the vertical structure.

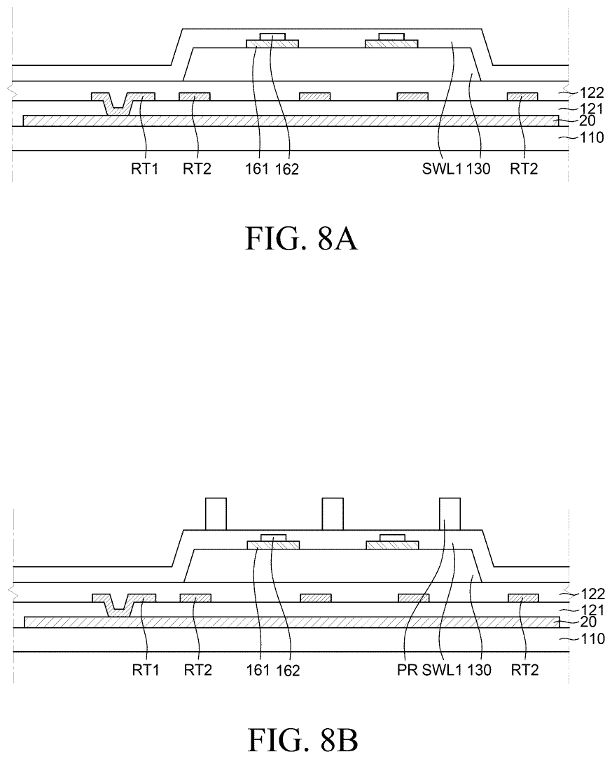

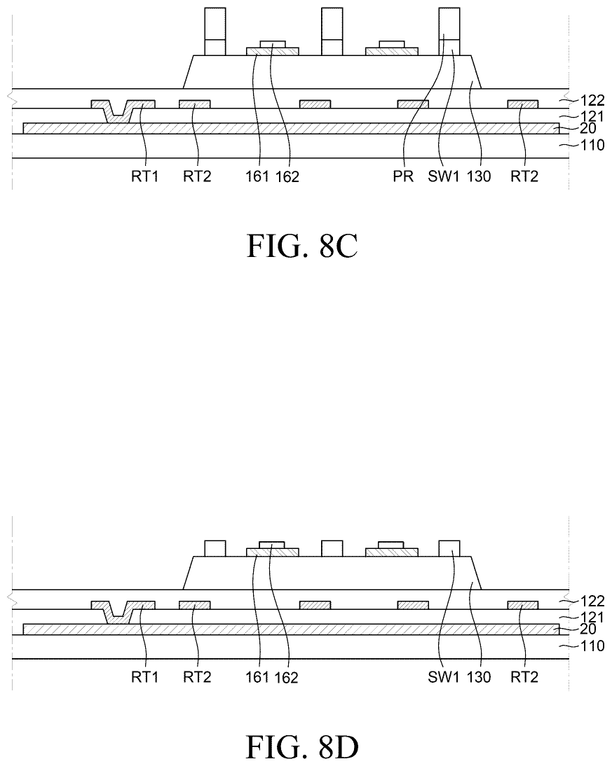

FIGS. 8A to 8D are views illustrating a method for manufacturing the first barrier rib of the display device according to one exemplary embodiment of the present disclosure. In FIGS. 8A to 8D, descriptions of contents overlapping with those described with reference to FIGS. 3 to 5 will be omitted.

First, referring to FIG. 8A, a first barrier rib layer SWL1 may be placed on the insulating layer 122, the bank pattern 130, and the solder pattern 162. The first barrier rib layer SWL1 may be made of the same material as the first barrier rib SW1 described above, but is not limited thereto.

Next, referring to FIG. 8B, a plurality of photosensitive resins PR may be disposed at positions where the plurality of barrier ribs SW is to be disposed. The plurality of photosensitive resins PR may be formed by patterning in a state where the photosensitive resins are disposed over the entire first barrier rib layer SWL1, but is not limited thereto.

Next, referring to FIG. 8C, a patterning process using the plurality of photosensitive resins PR as a mask may be performed to form the first barrier rib SW1. An etching process may be performed using the plurality of photosensitive resins PR as the mask to remove a portion of the first barrier rib layer SWL1 that does not overlap with the plurality of photosensitive resins PR, thereby forming the first barrier rib SW1.

Next, referring to FIG. 8D, the plurality of photosensitive resins PR may be removed. The plurality of photosensitive resins PR may be removed by a strip process, but is not limited thereto.

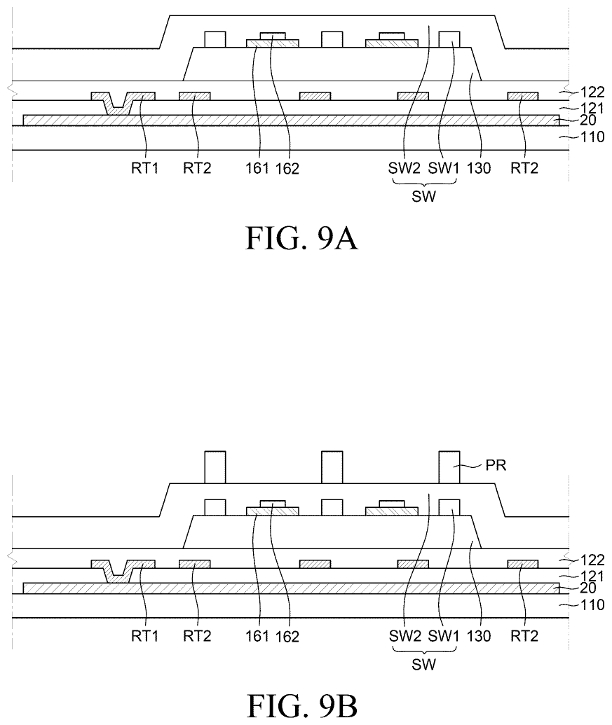

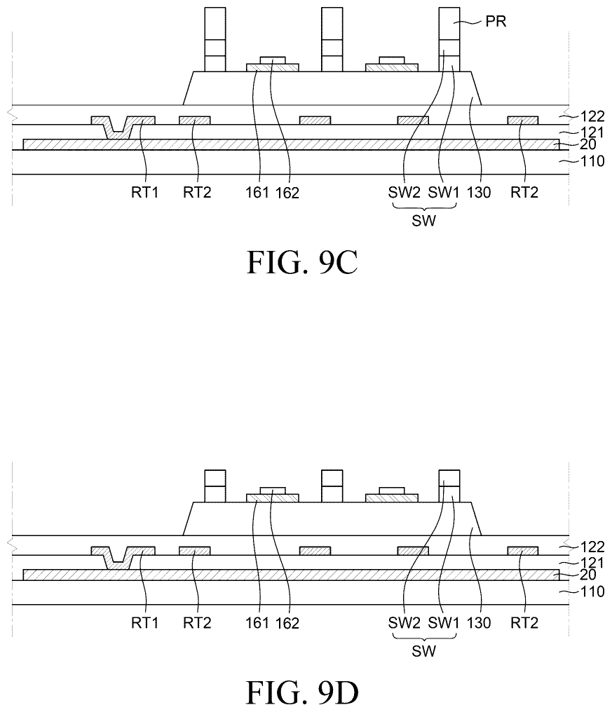

FIGS. 9A to 9D are views illustrating a method for manufacturing a second barrier rib of the display device according to one exemplary embodiment of the present disclosure.

In FIGS. 9A to 9D, descriptions of contents overlapping with those described with reference to FIGS. 3 to 5 will be omitted.

Referring to FIG. 9A, a second barrier rib layer SWL2 may be disposed on the insulating layer 122, the bank pattern 130, the solder pattern 162, and the first barrier rib SW1. The second barrier rib layer SWL2 may be made of the same material as the second barrier rib SW2 described above, but is not limited thereto.

Referring to FIG. 9B, a plurality of photosensitive resins PR may be disposed at the same positions as the positions where the plurality of first barrier ribs SW1 is disposed. The plurality of photosensitive resins PR may be formed by patterning in a state where the photosensitive resin is disposed over the entire second barrier rib layer SWL2, but is not limited thereto.

Next, referring to FIG. 9C, a patterning process using the plurality of photosensitive resins PR as a mask may be performed to form the second barrier rib SW2. An etching process may be performed using the plurality of photosensitive resins PR as the mask to remove a portion of the second barrier rib layer SWL2 that does not overlap with the plurality of photosensitive resins PR, thereby forming the second barrier rib SW2.

Next, referring to FIG. 9D, the plurality of photosensitive resins PR may be removed.

The plurality of photosensitive resins PR may be removed by a strip process, but is not limited thereto.

The second barrier rib SW2 may be covered on the insulating layer 122, the bank pattern 130, the first barrier rib SW1, and the solder pattern 162. The photosensitive resin PR may be patterned on the second barrier rib SW2 at a position overlapping the first barrier rib SW1. Thereafter, when an etching process is performed, the second barrier rib SW2 may be formed on the first barrier rib SW1. Without being limited thereto, the barrier rib SW may be formed as a single layer.

The display device according to the exemplary embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, home appliances, or the like. Moreover, the display device according to one or more exemplary embodiments of the present disclosure may be applied to an organic light-emitting lighting device or an inorganic light-emitting lighting device.

The exemplary embodiments of the present disclosure can also be described as follows:

According to an aspect of the present disclosure, there is provided a display device. The display device includes a plurality of first electrodes and a contact electrode disposed on a substrate, a plurality of barrier ribs disposed on the substrate, a plurality of light-emitting elements disposed between the plurality of barrier ribs on the plurality of first electrodes a first optical layer disposed between the plurality of light-emitting elements and a second electrode disposed on the plurality of light-emitting elements. The second electrode includes a first area disposed on the plurality of light-emitting elements and a second area extending outwardly from the first optical layer and electrically connected to the contact electrode.

The display device may further include a plurality of bank patterns disposed between the substrate and the plurality of first electrodes.

A size of the barrier rib may be different for each sub-pixel.

An upper surface of the barrier rib may be lower than an upper surface of the light-emitting element.

Two or more barrier ribs may be disposed on the bank.

The barrier rib may be constituted by a plurality of layers.

The barrier rib may be constituted by a single layer.

The display device may further include a second optical layer covering the second area of the second electrode.

A plurality of the second electrodes may be disposed spaced apart from each other for each pixel row. Each of the plurality of second electrodes may be electrically connected to the contact electrode.

The display device may further include an insulating layer disposed on the substrate, a plurality of connecting wires disposed between the substrate and the insulating layer and a pixel driving circuit connected to the plurality of connecting wires. The plurality of connecting wires may be electrically connected to the plurality of first electrodes and the contact electrode.

The first optical layer and the second optical layer may be made of different materials.

The first optical layer may include light scattering particles.

The display device may further include a plurality of signal wires extending between the plurality of bank patterns and connected to the plurality of first electrodes.

The contact electrode may be disposed between the plurality of signal wires.

The second electrode may further include a third area extending to a side surface of the first optical layer and connecting the first area and the second area.

The plurality of light-emitting elements may be inorganic light-emitting diodes.

The pixel driving circuit may be a driving driver.

According to another aspect of the present disclosure, there is provided a display device. The display device includes a substrate having a plurality of pixels defined thereon, each pixel including a plurality of sub-pixels, a pixel driving circuit disposed on the substrate, an insulating layer disposed on the pixel driving circuit, a plurality of bank patterns disposed on the insulating layer, a plurality of barrier ribs disposed on the plurality of bank patterns, a plurality of first electrodes disposed between the plurality of barrier ribs, a plurality of light-emitting elements disposed on at least some of the plurality of first electrodes and a second electrode disposed on the plurality of barrier ribs and the plurality of first electrodes.

The plurality of light-emitting elements may be disposed on all of the plurality of first electrodes. The second electrode may be electrically connected to the light-emitting element.

The display device may further include a first optical layer disposed between the plurality of light-emitting elements and the plurality of barrier ribs. The first optical layer may be disposed between the second electrode and the plurality of barrier ribs.

The plurality of light-emitting elements may be disposed on some of the plurality of first electrodes. A distance between the plurality of first electrodes and the second electrode in an area where the plurality of light-emitting elements is disposed may be greater than a distance between the plurality of first electrodes and the second electrode in an area where the plurality of light-emitting elements is not disposed.

The display device may further include a first optical layer disposed between the plurality of light-emitting elements and the plurality of barrier ribs.

In the area where the plurality of light-emitting elements is not disposed, the first optical layer may be disposed between the first electrode and the second electrode, and the second electrode may be in contact with an upper surface of the first optical layer.

In the area where the plurality of light-emitting elements is disposed, the plurality of light-emitting elements may be disposed between the first electrode and the second electrode, and the second electrode may be in contact with upper surfaces of the plurality of light-emitting elements and an upper surface of the first optical layer.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a plurality of first electrodes and a contact electrode disposed on a substrate;
a plurality of barrier ribs disposed on the substrate;
a plurality of light-emitting elements disposed between the plurality of barrier ribs on the plurality of first electrodes;
a first optical layer disposed between the plurality of light-emitting elements; and
a second electrode disposed on the plurality of light-emitting elements,
wherein the second electrode includes a first area disposed on the plurality of light-emitting elements and a second area extending outwardly from the first optical layer and electrically connected to the contact electrode.

2. The display device according to claim 1, further comprising a plurality of bank patterns disposed between the substrate and the plurality of first electrodes.

3. The display device according to claim 1, wherein a size of the barrier rib is different for each sub-pixel.

4. The display device according to claim 3, wherein an upper surface of the barrier rib is lower than an upper surface of the light-emitting element.

5. The display device according to claim 2, wherein two or more barrier ribs are disposed on the bank.

6. The display device according to claim 5, wherein the barrier rib is constituted by a plurality of layers.

7. The display device according to claim 5, wherein the barrier rib is constituted by a single layer.

8. The display device according to claim 1, further comprising a second optical layer covering the second area of the second electrode.

9. The display device according to claim 8, wherein a plurality of the second electrodes is disposed spaced apart from each other for each pixel row, and
each of the plurality of second electrodes is electrically connected to the contact electrode.

10. The display device according to claim 8, further comprising:
an insulating layer disposed on the substrate;
a plurality of connecting wires disposed between the substrate and the insulating layer; and
a pixel driving circuit connected to the plurality of connecting wires,
wherein the plurality of connecting wires is electrically connected to the plurality of first electrodes and the contact electrode.

11. The display device according to claim 1, wherein the first optical layer and the second optical layer are made of different materials.

12. The display device according to claim 11, wherein the first optical layer includes light scattering particles.

13. The display device according to claim 2, further comprising a plurality of signal wires extending between the plurality of bank patterns and connected to the plurality of first electrodes.

14. The display device according to claim 13, wherein the contact electrode is disposed between the plurality of signal wires.

15. The display device according to claim 1, wherein the second electrode further includes a third area extending to a side surface of the first optical layer and connecting the first area and the second area.

16. The display device according to claim 1, wherein the plurality of light-emitting elements is inorganic light-emitting diodes.

17. The display device according to claim 16, wherein the pixel driving circuit is a driving driver.

18. A display device comprising:
a substrate having a plurality of pixels defined thereon, each pixel including a plurality of sub-pixels;
a pixel driving circuit disposed on the substrate;
an insulating layer disposed on the pixel driving circuit;
a plurality of bank patterns disposed on the insulating layer;
a plurality of barrier ribs disposed on the plurality of bank patterns;
a plurality of first electrodes disposed between the plurality of barrier ribs;
a plurality of light-emitting elements disposed on at least some of the plurality of first electrodes; and
a second electrode disposed on the plurality of barrier ribs and the plurality of first electrodes.

19. The display device according to claim 18, wherein the plurality of light-emitting elements is disposed on all of the plurality of first electrodes, and
the second electrode is electrically connected to the light-emitting element.

20. The display device according to claim 19, further comprising a first optical layer disposed between the plurality of light-emitting elements and the plurality of barrier ribs, wherein the first optical layer is disposed between the second electrode and the plurality of barrier ribs.

21. The display device according to claim 18, wherein the plurality of light-emitting elements is disposed on some of the plurality of first electrodes, and a distance between the plurality of first electrodes and the second electrode in an area where the plurality of light-emitting elements is disposed is greater than a distance between the plurality of first electrodes and the second electrode in an area where the plurality of light-emitting elements is not disposed.

22. The display device according to claim 21, further comprising a first optical layer disposed between the plurality of light-emitting elements and the plurality of barrier ribs.

23. The display device according to claim 22, wherein, in the area where the plurality of light-emitting elements is not disposed, the first optical layer is disposed between the first electrode and the second electrode, and the second electrode is in contact with an upper surface of the first optical layer.

24. The display device according to claim 22, wherein, in the area where the plurality of light-emitting elements is disposed, the plurality of light-emitting elements is disposed between the first electrode and the second electrode, and the second electrode is in contact with upper surfaces of the plurality of light-emitting elements and an upper surface of the first optical layer.
